(19) United States
(12) Patent Application Publication
(10) Pub. No.: US 2015/0211718 A1
(43) Pub. Date: Jul. 30, 2015

(54) FLEXIBLE PRINTED CIRCUIT BOARD FOR ELECTRICALLY CONTACTING AND MECHANICALLY FIXING A LAMP IN A LUMINAIRE

(71) Applicant: OSRAM Opto Semiconductors GmbH, Regensburg (DE)

(72) Inventors: Karsten Diekmann, Rattenberg (DE); Simon Schicktanz, Regensburg (DE)

(73) Assignee: OSRAM Opto Semiconductors GmbH, Regensburg (DE)

(21) Appl. No.: 14/239,546

(22) PCT Filed: Oct. 12, 2012
(86) PCT No.: PCT/EP2012/070263

§ 371 Date: Feb. 19, 2014

(30) Foreign Application Priority Data
Oct. 12, 2011 (DE) 102011084326.4

(51) Int. Cl. F21V 17/12; F21V 23/00; H05K 1/11; H05K 1/18; H05K 1/02

(52) U.S. Cl. CPC F21V 17/12; H05K 1/181; H05K 1/028; H05K 1/115; H05K 1/189; F21V 23/004; F21Y 2101/02

(57) ABSTRACT

A printed circuit board which at least in sections is formed as a flexible printed circuit board may include: a first flat side at least one conductor track extending on the first flat side, and an electrically insulating cover layer partially coating the first flat side, wherein the at least one conductor track has an exposed contact section, for electrical contacting of the conductor track, wherein a through-hole, which extends fully through the printed circuit board in the thickness direction of the printed circuit board, and is formed in the printed circuit board, and wherein the exposed contact section of the conductor track is arranged next to the through-hole so that a mechanical fastening means, which has a shaft and a head, can be fitted with its shaft into the through-hole, the head directly contacting the exposed contact section.

### RELATED APPLICATIONS

The present application is a national stage entry according to 35 U.S.C. §371 of PCT application No.: PCT/EP2012/070263 filed on Oct. 12, 2012, which claims priority from German application No.: 10 2011 084 326.4 filed on Oct. 12, 2011, and is incorporated herein by reference in its entirety.

### TECHNICAL FIELD

The disclosure relates to a printed circuit board formed flexibly at least in sections (that is to say, for example, a so-called rigid-flex PCB or a so-called flex PCB), to a component having such a printed circuit board and to a luminaire having such a printed circuit board.

### BACKGROUND

Components, for example lamps, may for example be contacted with a flexible printed circuit board, for example a so-called flex PCB. To this end, for example, a first end section of the flexible printed circuit board may be electrically contacted with the component, for example by means of so-called ACF contacting. A second end section of the flexible printed circuit board may, for example, be electrically contacted with a mating connection piece via an exposed contacting region, so as to be able to connect the component via the flexible printed circuit board to the mating connection piece and supply it with electrical current. In the case of a lamp, the second end section is for example connected to a luminaire, or to an electrically conductive lamp connection element of the luminaire. To this end, for example, cables connected to the luminaire, or conductive wires thereon, may be soldered onto solder points formed on the flexible printed circuit board, so as to establish an electrical connection between the lamp and the luminaire.

During operation, or use, of the luminaire, an excessively large mechanical load may be applied to the solder points. This may lead to breaking or impairment of the electrical connection if appropriate precautions are not taken. Furthermore, the soldering process is elaborate and cables are required in order to electrically connect the exposed contacting region to the mating connection piece, or the luminaire.

### SUMMARY

According to various embodiments, a printed circuit board, a component, a luminaire and a luminaire are provided.

In/with particular embodiments of the disclosure, electrical contacting and mechanical fastening of a printed circuit board, which is formed flexibly in sections or entirely (referred to below as a flexible printed circuit board, for example a so-called flex PCB or a so-called rigid-flex PCB), with/to an electrically conductive mating connection piece can be achieved in a simple and rapid but reliable way.

The contacting and simultaneous fastening of the flexible printed circuit board may, for example, be carried out by employing/using a mechanical fastening element which, in particular, is made of an electrically conductive material. The soldering step/process described in the introduction can be fully obviated, that is to say the contacting can be formed solder-free. It is likewise possible to save on the cables which have previously been used in order to connect the contacting region of the printed circuit board to the mating connection piece, or the luminaire. The mechanical fastening and simultaneous electrical contacting may be formed directly by the mechanical fastening element, without the use of further elements, or substances/materials. That is to say, the fastening means may, for example, respectively contact or press together the exposed contact section and the mating connection piece directly. The application of the mechanical fastening element may in this case lead directly to the electrical contacting and simultaneous mechanical fastening of the flexible printed circuit board with/to the mating connection piece.

The mating connection piece may, for example, be a lamp connection element of a luminaire, for example a contact spring element or a perforated plate, with or without an internal screw thread (for example, the mating connection piece may be an electrically conductive screw hole). For example, a lamp, for example an OLED lamp or an OLED module, for example a flat OLED flat-light lamp, may in this case be connected on a further contacting region. This makes it possible for a luminaire assembler to integrate the lamp module rapidly, simply and operationally reliably into a luminaire.

Consequently, the flexible printed circuit board may be used according to particular embodiments of the disclosure in order to achieve electrical contacting and mechanical fastening of a lamp in a luminaire, i.e. to connect a lamp to a luminaire.

Particular embodiments of the disclosure may permit simple and rapid replacement of an OLED lamp, or an OLED module, with another OLED lamp of this type, or another OLED module of this type. For example, according to particular embodiments, the OLED module, or the printed circuit board connected thereto, may be fitted by means of a releasable connection, for example screwed, to a lamp connection element of a luminaire so that a user and/or lamp manufacturer can remove the screw by using a screwdriver, replace the OLED module, and subsequently refit and tighten the screw, so that the new OLED module can simultaneously be mechanically fastened to the luminaire and electrically contacted therewith. As an alternative to a screw, for example, it is possible to use a clamp which respectively contacts the exposed contacting region and the associated mating connection piece directly with a clamp section or, alternatively, presses the exposed contacting region and the associated mating connection piece against one another (in the latter case, the fastening element need not necessarily be formed electrically conductively).

Particular embodiments of the disclosure may achieve more stable, less delicate connection between a printed circuit board contacting region and a mating connection piece. For example, the use of screws or rivets as fastening means can lead to a robust form-fit and force-fit connection, which withstands the tensile stresses customarily occurring at the connection point.

In particular embodiments of the disclosure, tension relief of the connection between the printed circuit board contacting region and the mating connection piece may be provided, in order to further increase the stability of the connection.

According to one embodiment of the disclosure, a printed circuit board is provided which is formed in sections (for example a so-called rigid-flex PCB) or fully (a so-called flex PCB) as a flexible printed circuit board. A flexible printed circuit board, which is sometimes also referred to as an FPCB, may for example have a material layer or a multiplicity (in principle an arbitrary number) of printed circuit board layers. Furthermore, a flexible printed circuit board may have one or more (structured) electrically conductive layers, which may have one or more electrically conductive (for example metallic) conductor tracks. The printed circuit board may for example include plastic, for example polyimide, or be made thereof. For example, a flexible printed circuit board may be configured in the form of a thin/flat sheet or in the form of a thin/flat plate.

The flexible printed circuit board has a first flat side and a second flat side, which lie opposite one another in the thickness direction of the printed circuit board. At least one conductor track extends on the first flat side. The first flat side, and the conductor track formed thereon, are partially coated/covered with an electrically insulating cover layer. A surface section of the first flat side is left free by the cover layer so as to form a printed circuit board contacting region. In this printed circuit board contacting region, a contact section of the conductor track, used for electrical contacting of the conductor track, is exposed. As an alternative, the cover layer may be applied almost surface-wide onto the first flat side, in which case the respective contact section extends upward in the vertical direction through the cover layer.

A through-hole, which extends fully through the printed circuit board in the thickness direction of the printed circuit board, is formed in the printed circuit board. The through-hole may, for example, be formed circularly in plan view. For example, the through-hole may be formed by stamping or boring the printed circuit board.

The exposed contact section of the conductor track is in this case arranged next to the through-hole, so that a mechanical fastening means, which has a shaft and a head, can be fitted with its shaft into the through-hole, the head directly contacting the exposed contact section.

The contact section may, for example, directly bound the associated through-hole (in sections/partially or fully in the circumferential direction of the through-hole), i.e. directly adjoin the hole, or its wall. In other words, for example, a section of the wall of the through-hole may be formed by the contact section. That is to say, the contact section may extend as far as the through-hole. As an alternative, however, the contact section may also be arranged at a short distance from the through-hole. The shortest distance between the respective contact section and the associated through-hole may in this case be, for example, less than or equal to 5 mm, for example less than or equal to 4.5 mm, for example less than or equal to 3.5 mm, for example less than or equal to 3 mm, for example less than or equal to 2.5 mm, for example less than or equal to 2 mm, for example less than or equal to 1.5 mm, for example less than or equal to 1 mm, for example less than or equal to 0.5 mm.

In addition or as an alternative, the respective contact section may extend, for example fully, around the associated through-hole in the circumferential direction of the through-hole. In other words, the through-hole may, for example, extend through the exposed contact section of the conductor track and the underlying part of the printed circuit board (at or without a distance from the contact section). As an alternative, the respective contact section may extend around the associated through-hole only in sections/partially over an angle in the circumferential direction of the through-hole. This angle may be, for example, greater than or equal to 30°, for example, greater than or equal to 45°, for example, greater than or equal to 60°, for example, greater than or equal to 75°, for example, greater than or equal to 90°, for example, greater than or equal to 105°, for example, greater than or equal to 120°, for example, greater than or equal to 135°, for example, greater than or equal to 150°, for example, greater than or equal to 165°, for example, greater than or equal to 180°, for example, greater than or equal to 195°, for example, greater than or equal to 210°, for example, greater than or equal to 225°, for example, greater than or equal to 240°, for example, greater than or equal to 255°, for example, greater than or equal to 270°, for example, greater than or equal to 285°, for example, greater than or equal to 300°, for example, greater than or equal to 315°, for example, greater than or equal to 330°, for example, greater than or equal to 345°. The contact section extending (fully or partially) in the circumferential direction around the associated through-hole may in this case be formed by a continuous surface section (for example in the form of a ring) or alternatively by a plurality of surface sections which, for example, may be arranged at regular or irregular distances from one another around the through-hole.

A printed circuit board formed in such a way can consequently be contacted by introducing a mechanical fastening element (for example a screw, a pin or a rivet), which is made of an electrically conductive material, into the through-hole and mechanically fastening it (for example with a form and force fit) on a correspondingly formed mating connection piece (for example a perforated mating piece), so that an electrically conductive connection with the mating connection piece is simultaneously established. The fastening element may in this case respectively contact the contacting section and the mating connection piece directly. The flow of current takes place through the fastening element.

In the embodiment above, the printed circuit board may for example have a first and a second conductor track, both of which extend on the first flat side and each of which has an exposed (for example perforated) contact section which is arranged close to an associated through-hole of the printed circuit board. For example, precisely two conductor tracks may be provided, for example one conductor track which is assigned to a positive terminal of a current source and one conductor track which is assigned to a negative terminal of the current source. The contact sections may, for example, be arranged on a common printed circuit board contacting region or in two separate printed circuit board contacting regions (for example cover layer-free regions). The two conductor tracks may, for example, extend parallel to or concentrically with one another in sections.

In addition or as an alternative, in the embodiment above, the respective contact section may for example be formed annularly. The ring may, for example, be slit or be continuous. The ring may, for example, have a circular or square shape. The circular contact section forms an electrically conductive “contacting eyelet”, which can be contacted by the mechanical fastening means. For example, a screw or a rivet may contact the upper side of the ring with the lower side of its screw head or rivet head. The respective through-hole may, for example, extend through the ring opening of the associated “contacting eyelet”. Either the respective through-hole may in this case be directly bounded by the annular contact section (in which case the through-hole diameter corresponds to the inner diameter of the ring), or the through-hole may extend through the contact-section ring at a short distance from the inner circumference of the ring (the through-hole diameter is then slightly less than the inner diameter of the ring).

In addition or as an alternative, in the embodiment above, the respective contact section may be formed by a widened surface section of the respective conductor track. The at least one conductor track predominantly has a constant (narrow) width in plan view along its longitudinal extent. In the widened surface section, the conductor track has an increased width relative to the constant width. The through-hole may, for example, be formed/arranged centrally in the respective widened surface section.

In addition or as an alternative, in the embodiment above, the respective contact section may be formed on or by a longitudinal end section of the associated conductor track.

In addition or as an alternative, in the embodiment above, a plurality of or all contact sections may be formed on a common or the same end section of the printed circuit board.

In addition or as an alternative, in the embodiment above, a circumferentially/laterally protruding contacting tab may be formed by the printed circuit board. The respective contact section and the associated through-hole are then formed on or in the contacting tab. For example, the cover layer-free printed circuit board contacting region may be formed on the first flat side of the contacting tab.

In addition or as an alternative, in the embodiment above, the printed circuit board may have an elongate shape or an elongate section, for example a strip shape or a strip-shaped section. The contacting tab may, for example, in this case protrude from the end of the strip. As an alternative, the printed circuit board may have a ring shape or an annular section. The contacting tab may then, for example, protrude/project radially outward from the annular section.

In addition or as an alternative, in the embodiment above, the respective conductor track may be made of copper. Either the entire conductor track or merely the contact section thereof may, for example, be gold-plated or provided with another covering, or another coating, for example with Ni/Au plating or an Sn coating.

In addition or as an alternative, in the embodiment above, the cover layer may consist of polyimide or include polyimide.

In addition or as an alternative, in the embodiment above, one or more further through-holes may be formed in an electrically insulating region of the printed circuit board, that is to say at a significant distance from the respective conductor track. These holes are used to receive further fastening elements, which press the printed circuit board on the first flat side against a mating piece on which the printed circuit board bears with its lower side, so that tension relief of the connection formed on the contact section is achieved. As an alternative or in addition, the holes may be used to fasten the flexible printed circuit board on a component, or on a lamp. For example, one or more tabs formed by the printed circuit board (tension relief tabs/lugs or fastening tabs/lugs) may be provided, in which one or more of the further through-holes are respectively formed.

The printed circuit board according to the embodiment above may, for example, be electrically connected to a component. To this end, for example, the component may have an electrically conductive printed circuit board contact element for contacting of the printed circuit board, which is contacted by means of an anisotropic adhesive bond (ACF contacting) with a further contact section of the at least one conductor track. The further contact section of the conductor track may, for example, be formed on a first longitudinal end of the conductor track, the exposed contact section described above being formed on the other longitudinal end of the conductor track. The component may be formed as a lamp, for example as an OLED lamp (OLED: organic light-emitting diode), for example as a flat OLED flat-light lamp, for example as an OLED luminous tile. By means of the printed circuit board contact element of the lamp, a lamp electrode can thus be electrically connected to the flexible printed circuit board, or the conductor track thereof.

In addition or as an alternative, the printed circuit board according to the embodiment above may, for example, be electrically connected to a lamp connection device of a luminaire by means of the exposed contact section thereof. The printed circuit board is then a component of the luminaire. The lamp connection device may, for example, have one or more lamp connection elements. The respective lamp connection element may, for example, be made of metal and form a contact section mating piece. The respective lamp connection element may, for example, be a perforated metal piece, for example an electrically conductive screw hole, that is to say a hole having an internal screw thread. For example, the respective lamp connection element may be a contact spring element, for example a sheet-metal piece. One lamp connection element may be provided per conductor track, or per contact section.

In the luminaire above, the electrically conductive lamp connection element and the contact section of the conductor track may be connected to one another both mechanically and electrically by means of a mechanical fastening element (in particular directly, that is to say without further elements/substances).

The mechanical fastening element is, for example, in this case made of an electrically conductive material, so that the flow of current can take place through the fastening element.

The mechanical fastening element may, for example, in this case extend through the through-hole and therefore directly contact both the lamp connection element and the contact section.

For example, a blind hole or a through-hole, in which a section of the fastening element is received, i.e. extends through/into the fastening element, may be provided in the lamp connection element.

For example, a releasable connection may be formed by the electrically conductive fastening element.

For example, the electrically conductive lamp connection element may be a hole having an internal screw thread, into which a screw made of an electrically conductive material is screwed, the screw furthermore being introduced into the through-hole formed in the contact section and contacting the contact section, so that a mechanical and electrical connection between the lamp connection element and the contact section is simultaneously formed by the screw. For example, with its screw head the screw contacts a region of the contact section circumferentially adjoining the through-hole. The screw holes in the luminaire in this case simultaneously function as a mechanical and electrical contact element/connection element.

As an alternative, the screw may, for example, be inserted through a through-hole in the connection element and a nut may subsequently be fitted on the end section of the screw and tightened. In a similar way, the contact section and a perforated lamp connection element may be connected to one another directly by means of a rivet.

According to another embodiment of the disclosure, a luminaire which has the following components is provided:
a lamp,
a lamp connection device having one or more electrically conductive lamp connection elements for connecting the lamp to the luminaire, and
a printed circuit board formed flexibly at least in sections, which electrically contacts on the one hand the lamp and on the other hand the lamp connection device so that the lamp is electrically connected to the lamp connection device.

The printed circuit board has a first flat side, on which at least one conductor track extends/is formed. The first flat side and the conductor track are partially coated/covered with an electrically insulating cover layer. The at least one conductor track has an exposed contact section for electrical contacting of the conductor track.

The printed circuit board may, for example, be formed as described above for the first embodiment.

In order to establish the electrical contact between the printed circuit board and the lamp connection device, the contact section of the conductor track is connected directly (i.e. without using further elements or substances/materials apart from the mechanical fastening element) both mechanically and electrically to the lamp connection element by means of a mechanical fastening element.

A material fit, as produced for example by soldering (or adhesive bonding), is not necessary. Instead, the fastening means may form a form-fit and/or force-fit connection between the lamp connection element and the contact section. The fastening means may respectively contact the contact section and the lamp connection element directly. The fastening means is then, for example, made of an electrically conductive material. As an alternative, the fastening means may press the contact section and the lamp connection element against one another/onto one another; the fastening element does not then necessarily need to be made of an electrically conductive material, and may for example be a plastic clamp.

In the context of this application, a mechanical fastening element may therefore be understood as a fastening element which allows a material fit-free, form-fit and/or force-fit connection. For example, the mechanical fastening means may have the shape of a rod or pin, or may have a shaft. The mechanical fastening means may, for example, be formed rigidly.

A releasable mechanical connection between the contact section and the lamp connection element can be formed by the fastening element.

The connection formed by the fastening element may, for example, be a clamp connection or a screw connection or a rivet connection or a press-in connection or a plug-in connection or a latch connection (the same applies for the first embodiment).

The mechanical fastening element may, for example, be a pin or a bolt or a screw (optionally with a nut) or a rivet or a clamp (the same applies for the first embodiment). For example, the mechanical fastening element is formed non-flexibly and geometrically stably.

In both embodiments, a tension relief device may be provided for tension relief of the electrical and mechanical connection between the contact section and the lamp connection element.

The tension relief device may, for example, be formed by further through-holes formed in an electrically insulating region of the printed circuit board, through which a respective mechanical fastening element, which is fastened on a mating piece of the luminaire and is pressed against the mating piece by the one section of the printed circuit board, extends.

In addition or as an alternative, the tension relief device may have a clip fastened on the luminaire, by which a section of the printed circuit board is pressed against the luminaire. The clip may for example be made of a plastic material and/or may be a flat plate with a downwardly curved clamp section.

### BRIEF DESCRIPTION OF THE DRAWINGS

In the drawings, like reference characters generally refer to the same parts throughout the different views.

The drawings are not necessarily to scale, emphasis instead generally being placed upon illustrating the principles of the disclosed embodiments. In the following description, various embodiments described with reference to the following drawings, in which:

FIG. 1A and FIG. 1B respectively show a plan view of the upper flat side of a flex PCB according to the disclosure, wherein the upper cover layer being omitted in FIG. 1a in order to show the profile of the conductor tracks clearly;

FIG. 2 shows an OLED lamp, which is contacted on one side with the flex PCB according to the embodiment of FIG. 1B;

FIGS. 3 and 4 show an OLED lamp contacted on one side with the flex PCB according to the embodiment of FIG. 1B during mounting on a luminaire;

FIG. 5 shows a flex PCB according to another embodiment of the disclosure, connected to an OLED lamp, in plan view;

FIG. 6 shows a flex PCB according to yet another embodiment of the disclosure, connected to an OLED lamp, in plan view; and

FIGS. 7 and 8 respectively show a flex PCB according to yet another embodiment of the disclosure in plan view.

### DETAILED DESCRIPTION

The following detailed description refers to the accompanying drawing that show, by way of illustration, specific details and embodiments in which the disclosure may be practiced.

In the following detailed description, reference is made to the appended drawings, which form a part of this description and in which specific embodiments, in which the disclosure can be implemented, are shown for illustration. In this regard, direction terminology such as “up”, “down”, “forward”, “backward”, “front”, “rear”, etc. is used with reference to the orientation of the figure(s) being described. Since components of embodiments can be positioned in a number of different orientations, the direction terminology is used only for illustration and is in no way restrictive. It is to be understood that other embodiments may be used and structural or logical modifications may be carried out, without departing from the protective scope of the present disclosure. It is to be understood that the features of the various embodiments described herein may be combined with one another, unless specifically indicated otherwise. The following detailed description is therefore not to be interpreted in a restrictive sense, and the protective scope of the present disclosure is defined by the appended claims.

In the scope of this description, terms such as “connected” or “coupled” are used to describe both direct and indirect connection, and direct or indirect coupling. In the figures, elements which are identical or similar are provided with identical references, insofar as this is expedient.

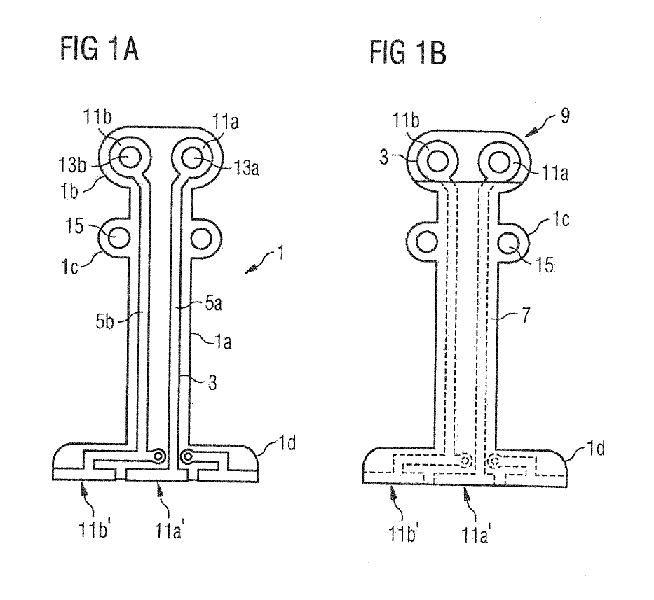

FIG. 1A and FIG. 1B show a flex PCB 1 according to a first embodiment of the disclosure in plan view. FIG. 1A in this case shows a plan view of the upper flat side 3 of the flex PCB 1, the upper cover layer 7 being omitted in order to show clearly the profile of the conductor tracks 5a and 5b. In FIG. 1B, the way in which the upper flat side 3 is partially coated with the upper cover layer 7 is shown.

As shown in FIG. 1A and FIG. 1B, the flex PCB 1 has an upper flat side 3, on which a first conductor track 5a and a second conductor track 5b extend, or are formed. The two conductor tracks 5a and 5b may in this case, for example, as shown in the figures, extend parallel to one another in sections, for example predominantly parallel to one another. The two conductor tracks 5a, 5b do not contact one another, that is to say they are arranged at a distance from one another. The respective conductor track 5a, 5b may, for example, be made of copper. At their upper longitudinal ends, the conductor tracks 5a and 5b respectively lead into a contact section 11a and 11b, which is formed here by a widened surface section of the respective conductor track. That is to say, on the respective contact section 11a, 11b, the conductor track is formed wider than in a region of the conductor track 5a, 5b next to the contact section.

The contact section 11a, 11b of the respective conductor track 5a, 5b (or alternatively the entire conductor track) may, for example, be gold-plated. At its lower end, the right-hand conductor track 5a leads into a further contact section 11a′. The left-hand conductor track 5b, conversely, branches to form two side limbs, each of which leads into a further contact section 11b′.

The exact profile of the respective conductor track 5a, 5b may be varied, and is not restricted to the profiles shown. Also, the contact sections 11a, 11b and the further contact sections 11a′, 11b′ do not necessarily need to be formed at the longitudinal ends of the respective conductor track. Furthermore, the number of conductor tracks is not limited to two; rather, as an alternative more than two conductor tracks or merely one conductor track may be provided.

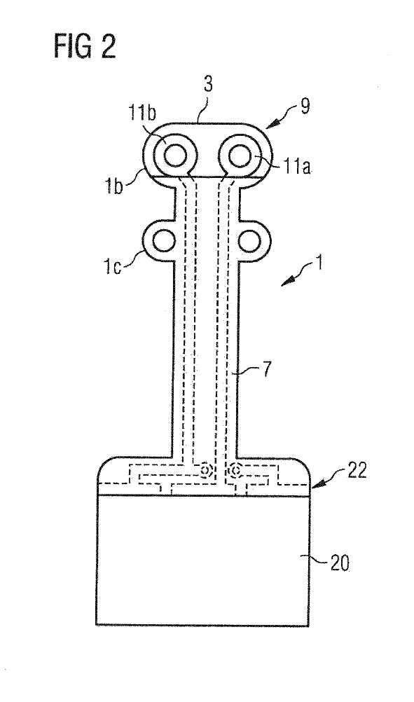

The respective contact section 11a, 11b at the upper longitudinal end of the conductor track 5a, 5b may, for example, be used for contacting of an electrically conductive lamp connection element (not shown) of a luminaire. The respective contact section 11a′, 11b′ at the lower longitudinal end of the conductor track 5a, 5b may, for example, be used for contacting of an electrically conductive printed circuit board contact element (not shown) of a lamp (see FIG. 2).

As shown in FIG. 1B, the upper flat side 3, including the conductor tracks 5a and 5b extending thereon, is partially coated with an electrically insulating upper cover layer 7. The upper cover layer 7 may, for example, consist of polyimide or include polyimide. On a cover layer-free, or polyimide-free, surface section of the upper flat side 3, a section of the two conductor tracks 5a, 5b is respectively exposed so that the conductor tracks can be electrically contacted at these positions. A so-called printed circuit board contacting region 9 is formed by the cover layer-free surface section. According to this embodiment, the two contact sections 11a, 11b are arranged in a continuous common printed circuit board contacting region 9. As an alternative, however, each contact section 11a, 11b could be accommodated in its own printed circuit board contacting region, i.e. two cover layer-free, or polyimide-free, surface sections spatially separated from one another would then need to be provided.

In the embodiment shown here, the respective contact section 11a, 11b arranged at the upper conductor track end is perforated, that is to say the printed circuit board 1 has a through-hole 13a, 13b in the region of the respective contact section 11a, 11b. The respective through-hole 13a, 13b extends in the printed circuit board thickness direction through the exposed contact section 11a, 11b and through the underlying remaining part of the printed circuit board 1. The respective through-hole 13a, 13b may, for example, be bored or stamped. The respective through-hole 13a, 13b may, for example, be directly bounded by the respective contact section, that is to say the respective contact section may for example form the bounding wall of the hole. The respective through-hole 13a, 13b may, for example, be arranged partially or fully inside the respective widened surface section 11a, 11b in plan view. The respective through-hole 13a, 13b may, for example, as shown in the plan view, be arranged centrally in the respective widened surface section 11a, 11b. As shown in the figures, the respective contact section may in this case be formed annularly, i.e. have a closed circular ring shape. According to another embodiment, however, the ring may also be slit and/or have a different shape, for example a square shape. An electrically conductive contacting eyelet is in this case formed by the respective annular contact element. This electrically conductive contacting eyelet may be electrically and mechanically contacted by an electrically conductive, mechanical fastening element, for example by a screw or a rivet.

As can furthermore be seen from FIG. 1A and FIG. 1B, the printed circuit board 1 according to this embodiment has an elongate strip section 1a, from which a plurality of tabs or tongues or lugs protrude circumferentially. According to an alternative embodiment, however, the printed circuit board may also be formed without such tabs. It is also possible to provide just one or a greater number of the tabs shown, that is to say not all the tabs shown need to be formed by the printed circuit board.

The tab 1b formed/protruding on the end side corresponds essentially to the printed circuit board contacting region 9, or the cover layer-free surface section 9. In other words, the two contact sections 11a, 11b are arranged on the upper flat side of the tab 1b, for which reason the tab 1b will also be referred to below as a contacting tab.

The two tabs or lugs 1c are arranged below the contacting tab 1b, that is to say between the upper contact sections 11a, 11b and the lower further contact sections 11a′, 11b′, and are used as tension relief tabs. The tension relief tabs 1c are respectively provided with a through-hole 15. These through-holes 15 (unlike the through-holes 13a, 13b, which according to this embodiment are directly bounded by the respective contact section) are formed in an electrically insulating region of the printed circuit board 1, that is to say at a distance from the conductor tracks 5a, 5b. The holes 15, or their bounding walls, may be reinforced, for example with eyelets.

At the longitudinal end of the strip section 1a opposite the contacting tab 1b, the printed circuit board 1 has a widened connecting section 1d, in which the lower further contact sections 11a′, 11b′ are arranged.

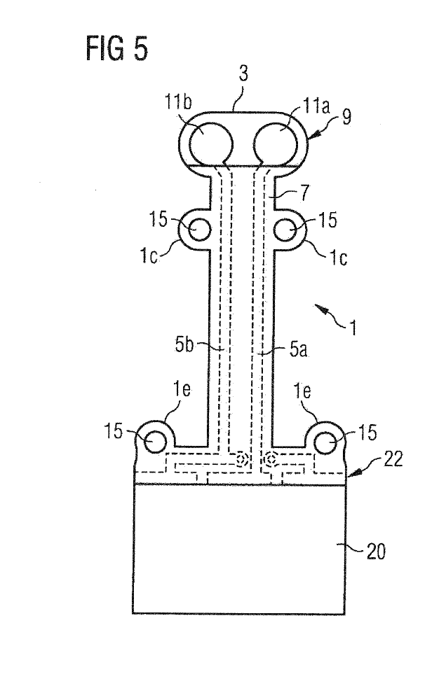

As indicated in FIG. 5, so-called component fastening tabs 1e may optionally be provided on the printed circuit board 1. The component fastening tabs 1e are perforated, so that the printed circuit board 1 can be mechanically fastened on the component with a suitable fastening element, for example a screw. The through-holes 15, like the through-holes 15 in the tension relief tabs 1c, are formed in an electrically insulating region of the printed circuit board 1 and may, for example, be reinforced with eyelets. The component fastening tabs 1e may, for example, protrude laterally/circumferentially from the above connecting section 1d.

The flexible neck section formed by the strip section 1a between the connecting section ld and the tension relief tab 1c may, for example, be about 0.5 to 5 cm long. The longitudinal distance between the tension relief tab 1c and the contacting tab 1b may, for example, be approximately 0.5 cm. These dimensions are in no way to be interpreted as restrictive, however, and other dimensions (as well as other shapes) may be selected for the printed circuit board 1.

FIG. 2 shows a component, here a flat tile-shaped OLED flat-light lamp 20, contacted with the flex PCB 1 described above. The OLED lamp 20 has a rectangular contour and is contacted on one side by the printed circuit board 1 along one rectangle side. The electrical connection of the lower/further contact sections 11a′, 11b′ to correspondingly formed printed circuit board contact elements (not shown) of the lamp may, for example, be carried out by means of so-called ACF contacting 22, that is to say with an anisotropic adhesive bond. In this way, the electrodes of the OLED lamp can be connected reliably to the conductor tracks 5a, 5b of the flex PCB 1, so that the OLED lamp 20 can be supplied with electrical current via the printed circuit board 1.

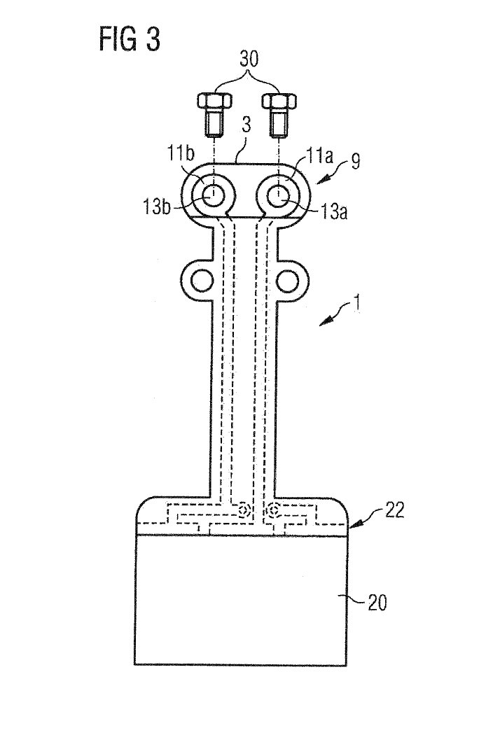

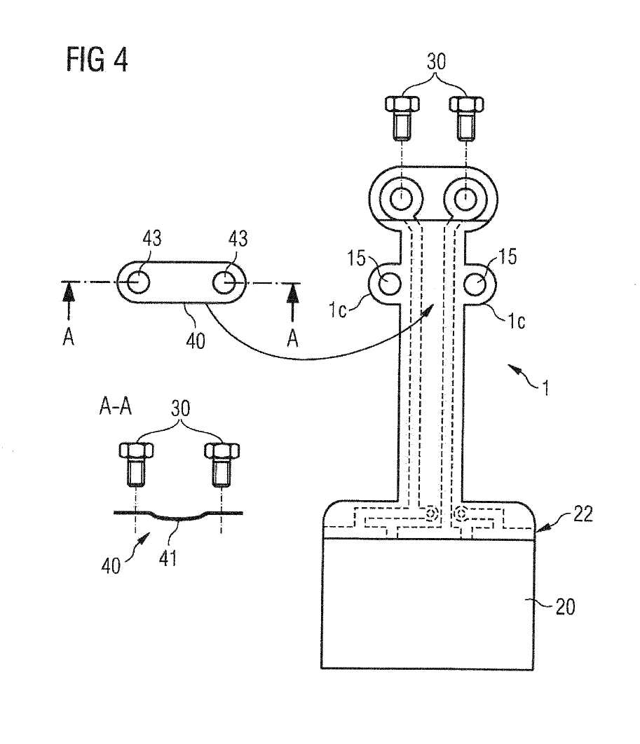

The mounting of the flex PCB described above onto/into a luminaire will be described in more detail below with reference to FIG. 3 and FIG. 4. In this case, it is shown that the flex PCB 1 with the lamp 20 fastened thereon can be connected particularly simply but nevertheless reliably to a luminaire system by a user or lamp manufacturer. That is to say, the flex PCB described above enables particularly simple and rapid but nevertheless operationally reliable integration of, for example, OLED components/modules into luminaires by the user or luminaire assembler.

First, the printed circuit board 1 is electrically connected with its printed circuit board contacting region 9, or the contact sections 11a, 11b arranged thereon/therein, to a lamp connection device (not shown) of a luminaire. The lamp connection device may, for example, have two metal lamp connection elements, or contact section mating pieces (one contact section mating piece per contact section), for example in the form of contact spring elements made of a metal sheet, or in the form of metal plates.

The electrical and mechanical connection of the respective contact section 11a, 11b to its associated contact section mating piece is in this case carried out by using a fastening element, which is made of an electrically conductive material. In this embodiment, for example, a screw or a rivet may be used since the contact sections 11a, 11b are perforated, as described above. According to this embodiment, the respective contact section mating piece is likewise perforated, for example a perforated metal plate. In the mounted state, the mechanical fastening element in this case extends on the one hand through the through-hole 13a, or 13b, and on the other hand through/into the hole provided in the contact section mating piece.

If a screw is used, then the hole (through-hole or blind hole) provided in the respective contact section mating piece may, for example, be provided with an internal screw thread. The screw 30 may then be screwed into the hole provided on the contact section mating piece, so that electrical and mechanical contact with the contact section mating piece is simultaneously produced. Furthermore, the screw 30 contacts the perforated contact section 11a, or 11b, for example with the lower side of its screw head, so that the contact section and the contact section mating piece are connected directly to one another by means of the screw 30. The screw holes formed on the luminaire, or the respective contact section mating piece, consequently function simultaneously as a mechanical and electrical contacting element/connection element.

According to an alternative embodiment, the hole provided in the respective contact section mating piece may be formed as a through-hole (an internal screw thread is not necessary in this case). The screw 30 is then fed with its longitudinal end section through the through-hole provided on the respective contact section mating piece. Subsequently, a nut is fitted on the longitudinal end section of the screw and tightened. According to this embodiment as well, the contact section and the respective contact section mating piece are electrically and mechanically connected directly to one another by means of the screw 30, including the nut.

When screws are used, replacement of individual OLED components by the user can be carried out particularly easily, for example when one of a plurality of OLED modules of a luminaire is defective. In other words, a feature common to the two alternatives described above is that a releasable mechanical connection between the contact section and the respective contact section mating piece is formed by the fastening element, or the screw.

According to another alternative, the screws 30 may, for example, be replaced by rivets, in which case the hole provided in the respective contact section mating piece is again formed as a through-hole.

According to another alternative, a clamp may be used in order to contact the respective contact section with the associated respective contact section mating piece. The contact sections 11a, 11b do not in this case need to be perforated, as indicated in FIG. 5. The respective contact section mating piece likewise does not need to be perforated, and may be formed by a spring contact element of the metal sheet type.

A feature common to all four alternatives described above is that, in order to establish the electrical contact between the printed circuit board and the lamp connection element, the contact section 11a, 11b of the respective conductor track is connectable/connected both mechanically and electrically directly and firmly by means of a mechanical fastening element, which is made of an electrically conductive material. A material fit, such as occurs during soldering, can be obviated. The connection of the printed circuit board and the lamp connection element may be carried out exclusively/merely using the separate fastening element, which produces/causes a form fit and/or force fit between the contact section and the respective contact section mating piece. Soldering can therefore be obviated. The contacting or fitting of a lamp on/in the luminaire may instead be carried out with commercially available fastening means, such as screws or rivets or clamps.

Besides the connections described above (clamp connection, screw connection and rivet connection) other connection techniques may also be envisioned, for example a press-in connection using a pin or a plug-in connection or a latch connection.

Before or after the printed circuit board 1 is connected with its printed circuit board contacting region 9 to the respective lamp connection element, tension relief of the above-described electrical and mechanical connection between the contact section and the respective contact section mating piece may optionally be provided.

To this end, for example, screws 30 are inserted through the holes 15 formed in the tension relief tabs 1c and screwed into corresponding screw holes, which are formed on a mating piece of the luminaire. In this way, the respective tab 1c is pressed downward by the screw head against the mating piece of the luminaire, so that tension relief of the above contacting is achieved.

As shown in FIG. 4, a tension relief clip 40 may also be used. The clip 40 may, for example, be made of a suitable plastic material. The clip 40 may, for example, have an elongate strip shape in plan view, the two longitudinal ends being perforated. The central longitudinal section 41 of the clip 40 may, for example, be bent downward (see section A-A in FIG. 4), so that a clamping and pressure section is formed. The clip 40 is placed onto the printed circuit board 1 in such a way that the holes 43 of the clip 40 are flush with the through-holes 15 of the tension relief tabs 1c. Subsequently, the screws 30 are fed as described above through the through-holes 15 and, for example, screwed into screw holes formed on a mating piece of the luminaire. In the mounted state, the lower side of the clip, in particular with the downwardly bent central section, presses the underlying section of the printed circuit board 1 against the luminaire, or against the mating piece of the luminaire.

Furthermore, before or after connection of the printed circuit board to the luminaire, or before and after provision of the tension relief, the printed circuit board 1 may additionally be fixed, for example screwed, on the component, or on the lamp 20, by means of the component fastening tabs 1e (see FIG. 5).

Other alternative embodiments of the printed circuit board 1 according to the disclosure will be described below.

FIG. 5 shows a flex PCB 1 according to another embodiment of the disclosure, connected to an OLED lamp. Elements which are the same or similar are provided with the same references. Repetition of the description of identical elements is avoided. According to this embodiment of the disclosure, the two upper contact sections 11a, 11b are formed surface-wide, that is to say no through-hole is provided in the respective contact section 11a, 11b. The contact sections 11a, 11b of this embodiment therefore have a circular surface shape, instead of the circular ring shape of the embodiment described above. Unlike in the previous embodiments, the printed circuit board does not have a through-hole in the close vicinity of the respective contact section. This embodiment is suitable, in particular, for contacting of the respective contact section 11a, 11b with a clamp (not shown). A first branch of the clamp then, for example, contacts the contact section 11a, a second branch of the clamp contacting the rear side of the contact section mating piece (for example a spring contact element or a sheet-metal plate) of the lamp connection device. The clamp branches connected by a bar press the lower side of the printed circuit board against the upper side of the contact section mating piece. As an alternative, the respective contact section 11a, 11b may also be placed directly onto the contact section mating piece (or the upper side thereof), the first clamp branch then pressing against the lower flat side of the printed circuit board 1. The clamp may then be made of an electrically insulating material.

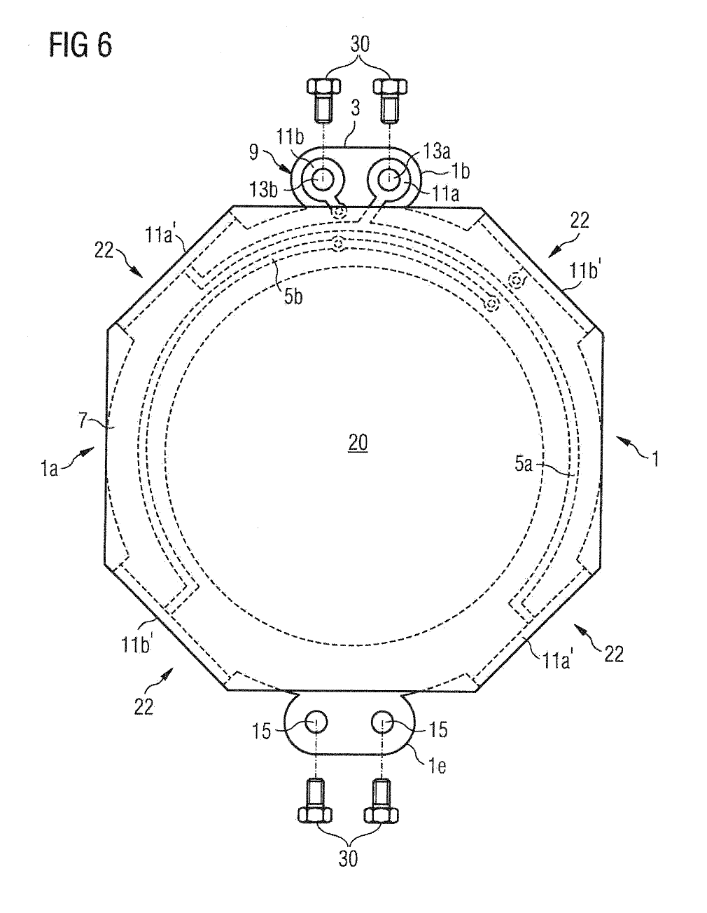

FIG. 6 shows a flex PCB 1 according to yet another embodiment of the disclosure. Parts which are the same or similar are again provided with the same references.

According to this embodiment, the printed circuit board 1 has a circular ring-shaped base section 1a, in which the two conductor tracks 5a, 5b extend concentrically with one another in sections. At a first longitudinal end, the two conductor tracks 5a, 5b lead into a respective contact section 11a, 11b, which is provided with a through-hole 13a, 13b that extends through the entire printed circuit board (in a similar way to the embodiment shown in FIG. 1). The two contact sections 11a, 11b are, as in the embodiment according to FIGS. 1A and 1B, arranged on/in a laterally/circumferentially protruding contacting tab 1b, on which the common printed circuit board contacting region 9 is provided.

In the circular ring-shaped base section 1a, the two conductor tracks 5a, 5b are covered by the insulating cover layer 7. Only in the printed circuit board contacting region 9 arranged on the contacting tab 1b are the conductor tracks, or the contact sections 11a, 11b thereof, exposed.

The conductor track 5a branches in the circular ring-shaped base section 1a, a first branch section extending to a first further contact section 11a′ and a second branch section extending to a second further contact section 11a′. In a similar way, the conductor track 5b branches in the circular ring-shaped base section 1a, a first branch section of the conductor track 5b extending to a third further contact section 11b′ and a second branch section of the conductor track 5b extending to a fourth further contact section 11b′. The lamp 20, which is configured here as an OLED flat-light lamp, can be contacted at various positions by means of the four contact sections 11a′ 11b′, of which there are four in total, for example in each case by means of ACF contacting.

The mechanical fastening and electrical contacting on the luminaire may be carried out as described for the first embodiment, for example by means of screws 30.

Furthermore, a component fastening tab 1e is also provided in this embodiment. Here, two through-holes 15 are formed in the component fastening tab 1e, so that the tab 1e can be screwed onto the component, or the lamp.

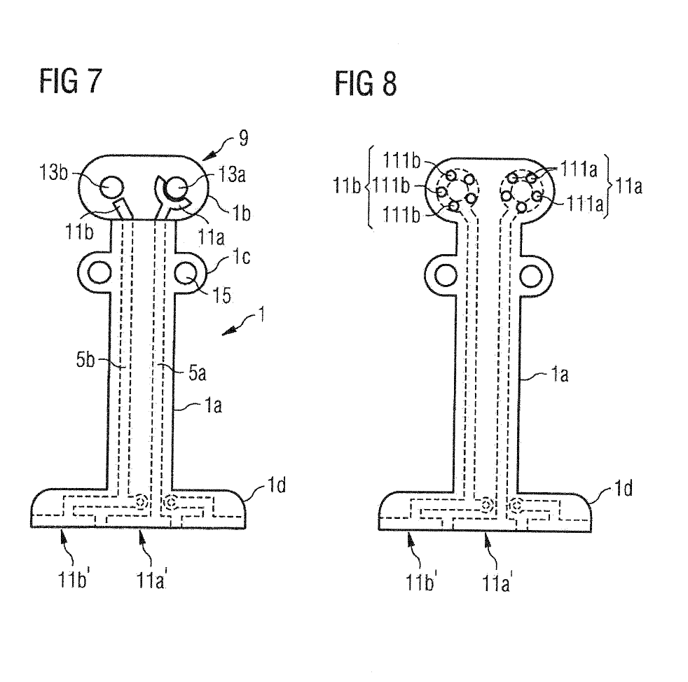

FIG. 7 shows a flex PCB 1 according to yet another embodiment of the disclosure. Parts which are the same or similar are again provided with the same references. Repetition of the description of identical elements is avoided.

According to this embodiment of the disclosure, the right-hand conductor track 5a leads at its upper longitudinal end into a circular arc-shaped contact section 11a. The contact section 11a encloses the associated through-hole 13a in the circumferential direction over an angle of about 180° and is arranged at a short distance from the through-holes 13a.

The left-hand conductor track 5b extends with its upper end in the direction of the through-hole 13b and ends close to the through-hole 13b. The upper longitudinal end section of the conductor track in this case forms the contact section 11b, which is arranged close to the through-hole 13b. The conductor track 5b has the same width at its contact section 11a as on the conductor track section extending in the strip section 1a.

The two contact sections 11a, 11b are arranged on the cover layer-free contacting region 9, which is in turn provided on the tab 1b.

As this embodiment of the disclosure shows, the two contact sections 11a, 11b do not necessarily need to be shaped identically, but may be shaped/formed differently.

Furthermore, the contact section does not necessarily need to have a particular shape or configuration; rather, according to particular embodiments it may be sufficient for the conductor track, for example with a constant or consistent width, to extend close enough to the through-hole so that an electrically conductive fastening element can contact the contact section with its head section.

FIG. 8 shows a flex PCB 1 according to yet another embodiment of the disclosure. Parts which are the same or similar are again provided with the same references. Repetition of the description of identical elements is avoided.

According to this embodiment of the disclosure, the cover layer 7 extends over almost all of the upper flat side 3 of the conductor track. The conductor tracks 5a and 5b lead at their respective upper longitudinal end into a circular ring section, which is arranged below the cover layer. From the respective circular ring section, one or a plurality of, here for example five, contact projections 111a and 111b, respectively, extend upward in the vertical direction and pass through the cover layer 7, so that they are exposed and can be electrically contacted. In other words, the contact projections 111a, 111b are left free by the cover layer. The contact projections 111a and 111b are respectively arranged directly adjacent or at a short distance around the associated through-hole. The contact projections 111a together form a ring-shaped contact section 11a, and the contact projections 111b together form a ring-shaped contact section 11b.

According to this embodiment of the disclosure, the contact sections 11a and 11b are thus formed not by a continuous surface section, but instead by a plurality of individualized surface sections (or contact projections), which in this case are arranged at regular distances from one another.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A printed circuit board, which at least in sections is formed as a flexible printed circuit board,
comprising: a first flat side least one conductor track extending on the first flat side, and
an electrically insulating cover layer partially coating the first flat side,
wherein the at least one conductor track has an exposed contact section, for electrical contacting of the conductor track,
wherein a through-hole, which extends fully through the printed circuit board in the thickness direction of the printed circuit board, and is formed in the printed circuit board, and
wherein the exposed contact section of the conductor track is arranged next to the through-hole so that a mechanical fastening means, which has a shaft and a head, can be fitted with its shaft into the through-hole, the head directly contacting the exposed contact section.

2. The printed circuit board as claimed in claim 1, having a first conductor track and a second conductor track, which extend on the first flat side and each have an exposed contact section, which is arranged next to an associated through-hole.

3. The printed circuit board as claimed in claim 1,
wherein the respective contact section is formed on a longitudinal end section of the associated conductor track.

4. The printed circuit board as claimed in claim 1,
wherein the respective contact section directly bounds the associated through-hole, or
wherein the shortest distance between the respective contact section and the associated through-hole is less than or equal to 5 mm.

5. The printed circuit board as claimed in claim 1,
wherein the respective contact section extends fully or in sections over an angle of greater than or equal to 30° around the associated through-hole in the circumferential direction of the through-hole.

6. The printed circuit board as claimed in claim 1,
wherein the respective contact section is formed annularly.

7. The printed circuit board as claimed in claim 1,
wherein a circumferentially protruding contacting tab, on or in which the respective contact section and the associated through-hole are formed, is formed by the printed circuit board.

8. A component, which is contacted with a printed circuit board which at least in sections is formed as a flexible printed circuit board,
the printed circuit board comprising:
a first flat side at least one conductor track extending on the first flat side, and
an electrically insulating cover layer partially coating the first flat side,
wherein the at least one conductor track has an exposed contact section, for electrical contacting of the conductor track,
wherein a through-hole, which extends fully through the printed circuit board in the thickness direction of the printed circuit board, and is formed in the printed circuit board, and
wherein the exposed contact section of the conductor track is arranged next to the through-hole so that a mechanical fastening means, which has a shaft and a head, can be fitted with its shaft into the through-hole, the head directly contacting the exposed contact section.

9. The component as claimed in claim 8,
having an electrically conductive printed circuit board contact element for contacting of the printed circuit board, which is contacted by means of an anisotropic adhesive bond with a further contact section of the at least one conductor track.

10. A luminaire, comprising
a lamp connection device for connecting a lamp to the luminaire, and
a printed circuit board which at least in sections is formed as a flexible printed circuit board,
the printed circuit board comprising:
a first flat side at least one conductor track extending on the first flat side, and
an electrically insulating cover layer partially coating the first flat side,
wherein the at least one conductor track has an exposed contact section, for electrical contacting of the conductor track,
wherein a through-hole, which extends fully through the printed circuit board in the thickness direction of the printed circuit board, and is formed in the printed circuit board, and
wherein the exposed contact section of the conductor track is arranged next to the through-hole so that a mechanical fastening means, which has a shaft and a head, can be fitted with its shaft into the through-hole, the head directly contacting the exposed contact section,
wherein the lamp connection device has one electrically conductive lamp connection element per exposed contact section, which is electrically connected to the associated contact section.

11. The luminaire as claimed in claim 10,
wherein the respective electrically conductive lamp connection element and the associated contact section are connected to one another by a mechanical fastening element both mechanically and electrically, and wherein the respective fastening element is made from an electrically conductive material which extends through the associated through-hole and directly contacts both the associated contact section and the associated lamp connection element.

12. The luminaire as claimed in claim 11,
wherein the respective fastening element is a screw, and wherein a hole having an internal screw thread, into which the associated screw can be screwed, is formed by the respective lamp connection element.

13. A luminaire, comprising
a lamp,
a lamp connection device for connecting the lamp to the luminaire, and
a printed circuit board formed flexibly at least in sections, which electrically contacts on the one hand the lamp and on the other hand the lamp connection device so that the lamp is electrically connected to the luminaire via the printed circuit board,
wherein the printed circuit board has a first flat side, on which at least one conductor track extends,
wherein the first flat side is partially coated with an electrically insulating cover layer,
wherein the at least one conductor track has an exposed contact section, for electrical contacting of the conductor track, which extends through the cover layer or is arranged in a surface region of the first flat side by the cover layer,
wherein, in order to establish the electrical contact between the printed circuit board and the lamp connection device, the exposed contact section of the at least one conductor track is directly connected both mechanically and electrically to an electrically conductive lamp connection element of the lamp connection device by means of a mechanical fastening element.

14. The luminaire as claimed in claim 11, wherein
a releasable mechanical connection between the contact section of the conductor track and the lamp connection element is formed by the respective fastening element, and/or
the respective mechanical fastening element is a pin or a bolt or a screw or a rivet or a clamp.

15. The luminaire as claimed in claim 10, further comprising a tension relief device applied on the printed circuit board for tension relief of the electrical and mechanical connection between the respective contact section and the associated lamp connection element.

16. The luminaire as claimed in claim 13, wherein
a releasable mechanical connection between the contact section of the conductor track and the lamp connection element is formed by the respective fastening element, and/or
the respective mechanical fastening element is a pin or a bolt or a screw or a rivet or a clamp.

17. The luminaire as claimed in claim 13,
further comprising a tension relief device applied on the printed circuit board for tension relief of the electrical and mechanical connection between the respective contact section and the associated lamp connection element.

18. The printed circuit board as claimed in claim 1, wherein
the exposed contact section extends through the cover layer or is arranged in a surface region of the first flat side by the cover layer.
